(19) United States
(12) Patent Application Publication
(10) Pub. No.: US 2010/0258869 A1
(43) Pub. Date: Oct. 14, 2010

(54) SEMICONDUCTOR DEVICE AND MANUFACTURING METHOD THEREOF

(75) Inventors: Yusuke MORITA, Akishima (JP); Ryuta Tsuchiya, Tokyo (JP); Takashi Ishigaki, Hino (JP); Hiroyuki Yoshimoto, Kawasaki (JP); Nobuyuki Sugii, Tokyo (JP); Shinichiro Kimura, Kunitachi (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/757,090

(22) Filed: Apr. 9, 2010

(30) Foreign Application Priority Data
Apr. 10, 2009 (JP) JP2009-095755

(51) Int. Cl. H01L 27/12; H01L 21/336

(52) U.S. Cl. 257/347; 438/158; 257/E27.111; 257/E21.414

(57) ABSTRACT

An n well and a p well disposed at a predetermined interval on a main surface of a SOI substrate with a thin BOX layer are formed, and an nMIS formed on the p well has a pair of n-type source/drain regions formed on semiconductor layers stacked on a main surface of the SOI layer at a predetermined distance, a gate insulating film, a gate electrode and sidewalls sandwiched between the pair of n-type source/drain regions. A device isolation is formed between the n well and the p well, and a side edge portion of the device isolation extends toward a gate electrode side more than a side edge portion of the n-type source/drain region (sidewall of the BOX layer).

### CROSS-REFERENCE TO RELATED APPLICATION

The present application claims priority from Japanese Patent Application No. 2009-095755 filed on Apr. 10, 2009, the content of which is hereby incorporated by reference into this application.

### TECHNICAL FIELD OF THE INVENTION

The present invention relates to a semiconductor device and a manufacturing technique thereof, and more particularly to a technique effectively applied to the manufacture of a device isolation provided in a substrate for electrically isolating a first semiconductor region of a first conductivity type and a second semiconductor region of a second conductivity type different from the first conductivity type.

### BACKGROUND OF THE INVENTION

The speeding up, lower power consumption, multifunctionality and cost reduction have been demanded for a large-scale integrated circuit used in a microcomputer for a digital home appliance or a personal computer or an analog radio-frequency electronic component (for example, transmission amplifier, reception integrated circuit and others) used in a mobile communication terminal. In an electronic device which makes up a circuit, for example, a field effect transistor, its performance has been improved (improvement in current driving force, reduction in power consumption and others) mainly by reducing the gate length by making full use of the lithography technique. However, in a MISFET (Metal Insulator Semiconductor Field Effect Transistor) representing the field effect transistor, when the gate length is reduced to 100 nm or shorter, the variation in threshold voltage occurs due to the variation in device dimensions such as the gate length or the statistical fluctuation of impurities, which prevents the performance improvement of the MISFET.

Therefore, in order to prevent the above-described problem, for example, as described in Technical Digest of International Electron Devices Meeting 2004, pp. 631-634 (Non-Patent Document 1), a technique has been studied, in which an SOI (silicon On Insulator) substrate having an SOI layer and a BOX (Buried Oxide) layer each thinned to 10 nm or less (hereinafter, referred to as SOI substrate with a thin BOX layer) is used to form a field effect transistor on this SOI substrate with a thin BOX layer, a channel impurity concentration is lowered, and an impurity concentration of a support substrate below the BOX layer is adjusted, thereby controlling the threshold voltage of the field effect transistor.

Since the channel impurity concentration can be lowered in the field effect transistor formed on the SOI substrate with a thin BOX layer, the variation in threshold voltage due to the statistical fluctuation of impurities can be reduced. Further, since the BOX layer is as thin as about 10 nm, the threshold voltage can be controlled by adjusting the impurity concentration of the support substrate below the BOX layer. Also, the variation in threshold voltage due to the modulation in gate length and thickness of the SOI substrate (statistical variation) can be prevented by controlling the back gate bias from the support substrate side through the BOX layer.

However, since the SOI layer of the field effect transistor formed on the SOI substrate with a thin BOX layer is as thin as about 10 nm, the parasitic resistance of source/drain region is increased. Note that the increase in parasitic resistance can be prevented by performing, for example, the selective epitaxial growth (SEG) and forming a low-resistance silicide layer thereon by silicidation.

### SUMMARY OF THE INVENTION

In order to support various applications, an SOI device and a bulk device for high operation voltage have to be integrated together on the same SOI substrate with a thin BOX layer in some cases. A method of forming a bulk device on a SOI substrate with a thin BOX layer includes a hybrid technique in which a bulk device is formed in a region from which an SOI layer and a BOX layer have been removed. By applying this technique, a bulk device can be provided on a SOI substrate with a thin BOX layer. However, since an SOI layer (thickness: about 10 nm) and a BOX layer (thickness: about 10 nm) have been removed, the difference in height (step) between an upper surface of a device isolation and an upper surface of a support substrate in the region where the bulk device is to be formed (bulk device region) becomes larger than the difference in height (step) between an upper surface of the device isolation and an upper surface of the support substrate in the region where the SOI device is to be formed (SOI device region) by the total thickness of the SOI layer and the BOX layer.

Meanwhile, in the case of a field effect transistor formed on a SOI substrate with a thin BOX layer, when the selective epitaxial growth and the silicidation are performed, cleaning using hydrofluoric acid (HF) solution is certainly carried out as preprocessing for removing a cap oxide film on a gate electrode (for example, SiO₂ film) and a natural oxide layer formed on an upper surface of a support substrate and an upper surface of an SOI layer. However, this HF cleaning etches not only the natural oxide layer on the upper surface of the support substrate and the upper surface of the SOI layer but an oxide film (for example, SiO₂ film) of the device isolation region.

When the oxide film of the device isolation is etched and recessed (lowered in height), the SOI layer and the support substrate below the device isolation can be electrically in contact with each other, and leakage current flows from the source/drain region to the support substrate in some cases. This substrate leakage current can be prevented by raising the height of the oxide-film surface of the device isolation region, but when the oxide film of the device isolation is raised, the step between the upper surface of the device isolation and the upper surface of the SOI layer is enlarged in the SOI device region and the step between the upper surface of the device isolation and the upper surface of the support substrate is enlarged in the bulk device region. When the gate electrode is processed in the state where these steps are large, residues of the gate electrode material are left at the step. Although the over-etching is necessary for removing the residues, if the over-etching amount is increased, the SOI layer on both sides of the gate electrode is excessively removed in the SOI device region.

The upper limit of the step between the upper surface of the device isolation and the upper surface of the SOI layer or the step between the upper surface of the device isolation and the upper surface of the support substrate for preventing the occurrence of the residue or the excessive removal of a substrate when the gate electrode is processed is difficult to be strictly defined because of the gate electrode materials and the etching conditions, but it is about 20 nm. Also, the lower limit of the step between the upper surface of the device isolation and the upper surface of the SOI layer for preventing the substrate leakage current is difficult to be strictly defined because it depends on the thickness of the cap oxide film on the gate electrode, but it is about 10 nm. In other words, the step between the upper surface of the device isolation and the upper surface of the SOI layer and the step between the upper surface of the device isolation and the upper surface of the support substrate have to be designed to 10 to 20 nm.

However, as described above, when forming the hybrid structure, the step of about 20 nm is formed between the upper surface of the SOI layer in the SOI device region and the upper surface of the support substrate in the bulk device region. Therefore, the design inconsistency is caused when the step between the upper surface of the device isolation and the upper surface of the SOI layer and the step between the upper surface of the device isolation and the upper surface of the support substrate are set within the range of 10 to 20 nm. Accordingly, some measures in process have to be taken for forming the hybrid structure.

Also, in addition to the above-described problem in process, a field effect transistor formed on a SOI substrate with a thin BOX layer is inferior in some characteristics when compared with a field effect transistor formed on a thick film BOX-SOI substrate. It is a problem of the increase in junction capacitance caused between the source/drain region and the support substrate. Since this junction capacitance is negligibly low when the BOX layer is sufficiently thick, the influence on the circuit delay time is small. However, this junction capacitance increases as the thickness of the BOX layer decreases, and when the thickness of the BOX layer is about 10 nm, the magnitude of the junction capacitance becomes almost equal to the junction capacitance of the field effect transistor formed in the bulk device region. When the junction capacitance increases, it affects the high-speed circuit operation, and therefore, some structural measures have to be taken for showing the advantage over the field effect transistor formed in the bulk device region.

As described above, the objectives on the process to be achieved for fabricating a field effect transistor on a SOI substrate with a thin BOX layer include the prevention of the substrate leakage current and the prevention of the occurrence of the excessive removal of a substrate or the residues when processing the gate electrode. Also, the objectives on the structure to be achieved include the reduction in junction capacitance between the source/drain region and the support substrate.

An object of the present invention is to provide a technique capable of preventing the degradation in reliability and operation characteristics of a field effect transistor formed on a SOI substrate with a thin BOX layer.

The above and other objects and novel characteristics of the present invention will be apparent from the description of the present specification and the accompanying drawings.

The typical ones of the inventions disclosed in the present application will be briefly described as follows.

An embodiment of the present invention is a semiconductor device having a field effect transistor formed on a SOI substrate with a thin BOX layer made up of a silicon substrate and an SOI layer formed on a main surface of the silicon substrate via a BOX layer. The field effect transistor includes: a first semiconductor region of a first conductivity type and a second semiconductor region of a second conductivity type different from the first conductivity type disposed at a predetermined interval on a main surface of the SOI substrate with a thin BOX layer; a pair of semiconductor layers disposed at a predetermined distance on a main surface of the first semiconductor region; a pair of source/drain regions of the second conductivity type formed on the pair of semiconductor layers; a gate electrode sandwiched between the pair of source/drain regions; and a device isolation formed between the first semiconductor region and the second semiconductor region, and a side edge portion of the device isolation extends toward a gate electrode side more than a side edge portion of the source/drain region.

Another embodiment of the present invention is a manufacturing method of a semiconductor device having a field effect transistor formed on a SOI substrate with a thin BOX layer made up of a silicon substrate and an SOI layer formed on a main surface of the silicon substrate via a BOX layer. After forming a first semiconductor region of a first conductivity type and a second semiconductor region of a second conductivity type different from the first conductivity type disposed at a predetermined interval on a main surface of the SOI substrate with a thin BOX layer, a gate insulating film and a gate electrode are formed on a main surface of the SOI layer in the first semiconductor region, and further, a sidewall made of an insulating film is formed on a side wall of the gate electrode. Subsequently, a semiconductor layer is formed on the main surface of the SOI layer having no gate electrode and sidewall formed thereon, and a pair of source/drain regions of the second conductivity type is formed on the semiconductor layer. Then, after forming an interlayer insulating film on the main surface of the SOI substrate with a thin BOX layer, the interlayer insulating film, the semiconductor layer and the SOI layer located on a position between the first semiconductor region and the second semiconductor region are sequentially etched, thereby forming a first isolation trench in the interlayer insulating film, the semiconductor layer and the SOI layer. Subsequently, after forming an oxide film sidewall on the semiconductor layer and the SOI layer exposed on the side wall of the first isolation trench, the BOX layer located below the first isolation trench is removed to form a second isolation trench, and further, the silicon substrate is isotropically etched from the region where the BOX layer has been removed, thereby forming a third isolation trench in the silicon substrate. A side edge portion of the third isolation trench is formed to extend toward a gate electrode side more than a side edge portion of the source/drain region. Thereafter, the first, second and third isolation trenches are embedded with an insulating material.

The effects obtained by typical embodiments of the present invention will be briefly described below.

By preventing the substrate leakage current, preventing the occurrence of the excessive removal of a substrate and the residues when processing the gate electrode and reducing the junction capacitance between the source/drain region and the support substrate, the degradation in the reliability and the operation characteristics of the field effect transistor formed on a SOI substrate with a thin BOX layer can be prevented.

### BRIEF DESCRIPTIONS OF THE DRAWINGS

FIG. 1 is a cross-sectional view of the principal part of a semiconductor device according to a first embodiment of the present invention;

FIG. 2 is a plan view of the principal part of the semiconductor device according to the first embodiment of the present invention;

FIG. 3 is a cross-sectional view of the principal part in a manufacturing process of the semiconductor device according to the first embodiment of the present invention;

FIG. 4 is a cross-sectional view of the principal part showing the same section as that of FIG. 3 in the manufacturing process of the semiconductor device continued from FIG. 3;

FIG. 5 is a cross-sectional view of the principal part showing the same section as that of FIG. 3 in the manufacturing process of the semiconductor device continued from FIG. 4;

FIG. 6 is a cross-sectional view of the principal part showing the same section as that of FIG. 3 in the manufacturing process of the semiconductor device continued from FIG. 5;

FIG. 7 is a cross-sectional view of the principal part showing the same section as that of FIG. 3 in the manufacturing process of the semiconductor device continued from FIG. 6;

FIG. 8 is a cross-sectional view of the principal part showing the same section as that of FIG. 3 in the manufacturing process of the semiconductor device continued from FIG. 7;

FIG. 9 is a cross-sectional view of the principal part showing the same section as that of FIG. 3 in the manufacturing process of the semiconductor device continued from FIG. 8;

FIG. 10 is a cross-sectional view of the principal part showing the same section as that of FIG. 3 in the manufacturing process of the semiconductor device continued from FIG. 9;

FIG. 11 is a cross-sectional view of the principal part showing the same section as that of FIG. 3 in the manufacturing process of the semiconductor device continued from FIG. 10;

FIG. 12 is a cross-sectional view of the principal part showing the same section as that of FIG. 3 in the manufacturing process of the semiconductor device continued from FIG. 11;

FIG. 13 is a cross-sectional view of the principal part showing the same section as that of FIG. 3 in the manufacturing process of the semiconductor device continued from FIG. 12;

FIG. 14 is a cross-sectional view of the principal part showing the same section as that of FIG. 3 in the manufacturing process of the semiconductor device continued from FIG. 13;

FIG. 15 is a cross-sectional view of the principal part showing the same section as that of FIG. 3 in the manufacturing process of the semiconductor device continued from FIG. 14;

FIG. 16 is a cross-sectional view of the principal part of a semiconductor device according to a second embodiment of the present invention;

FIG. 17 is a cross-sectional view of the principal part in a manufacturing process of the semiconductor device according to the second embodiment of the present invention;

FIG. 18 is a cross-sectional view of the principal part showing the same section as that of FIG. 17 in the manufacturing process of the semiconductor device continued from FIG. 17;

FIG. 19 is a cross-sectional view of the principal part showing the same section as that of FIG. 17 in the manufacturing process of the semiconductor device continued from FIG. 18;

FIG. 20 is a cross-sectional view of the principal part showing the same section as that of FIG. 17 in the manufacturing process of the semiconductor device continued from FIG. 19;

FIG. 21 is a cross-sectional view of the principal part showing the same section as that of FIG. 17 in the manufacturing process of the semiconductor device continued from FIG. 20;

FIG. 22 is a cross-sectional view of the principal part showing the same section as that of FIG. 17 in the manufacturing process of the semiconductor device continued from FIG. 21;

FIG. 23 is a cross-sectional view of the principal part showing the same section as that of FIG. 17 in the manufacturing process of the semiconductor device continued from FIG. 22;

FIG. 24 is a cross-sectional view of the principal part showing the same section as that of FIG. 17 in the manufacturing process of the semiconductor device continued from FIG. 23; and

FIG. 25 is a cross-sectional view of the principal part showing the same section as that of FIG. 3 in the manufacturing process of the semiconductor device continued from FIG. 24.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, in the embodiments below, a MISFET representing a field effect transistor is abbreviated as MIS, a p-type MISFET is abbreviated as pMIS and an n-type MISFET is abbreviated as nMIS. Further, components having the same function are denoted by the same reference symbols throughout the drawings for describing the embodiment, and the repetitive description thereof will be omitted. Hereinafter, embodiments of the present invention will be described in detail with reference to the accompanying drawings.

### First Embodiment

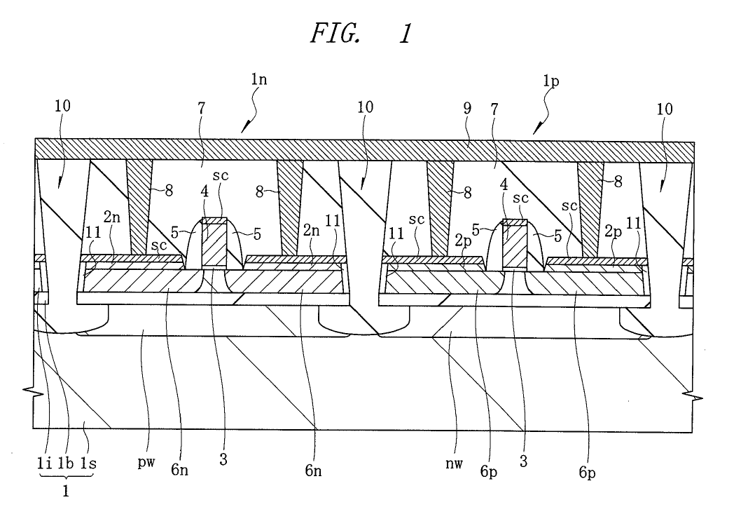

A semiconductor device and a manufacturing method thereof according to the first embodiment will be described in detail with reference to FIG. 1 to FIG. 15.

First, the structure of the semiconductor device according to the first embodiment will be described with reference to FIG. 1. FIG. 1 shows a cross-sectional view of the principal part of the semiconductor device according to the first embodiment.

The semiconductor device according to the first embodiment has an n channel MIS transistor 1n (hereinafter, simply referred to as nMIS n1) and a p channel MIS transistor 1p (hereinafter, simply referred to as pMIS p1) formed on a SOI substrate with a thin BOX layer 1. The SOI substrate with a thin BOX layer 1 is a substrate in which an SOI layer 1i is formed on a main surface of a silicon substrate 1s via a BOX layer 1b. A thickness of the BOX layer 1b is, for example, 3 nm to 50 nm and a typical thickness is, for example, 10 nm. Also, a thickness of the SOI layer 1i is, for example, 4 nm to 100 nm and a typical thickness is, for example, 12 nm. Here, the n-type indicates a conductivity type or a conductive state of a semiconductor region in which majority carriers are electrons, and the p-type indicates a conductivity type or a conductive state of a semiconductor region in which majority carriers are holes. Note that it does not matter whether the conductivity type of the silicon substrate 1s and the SOI layer 1i that make up the SOI substrate with a thin BOX layer 1 is the p-type or the n-type.

The nMIS 1n has a pair of n-type source/drain regions 2n made of an n-type semiconductor layer and formed so as to be stacked on a main surface of the SOI layer 1i (p well pw) of the SOI substrate with a thin BOX layer 1. The pair of n-type source/drain regions 2n is disposed at a predetermined interval on the main surface of the SOI substrate with a thin BOX layer 1. The pMIS 1p has a pair of p-type source/drain regions 2p made of a p-type semiconductor layer and formed so as to be stacked on the main surface of the SOI layer 1i (n well nw) of the SOI substrate with a thin BOX layer 1. The pair of p-type source/drain regions 2p is disposed at a predetermined interval on the main surface of the SOI substrate with a thin BOX layer 1.

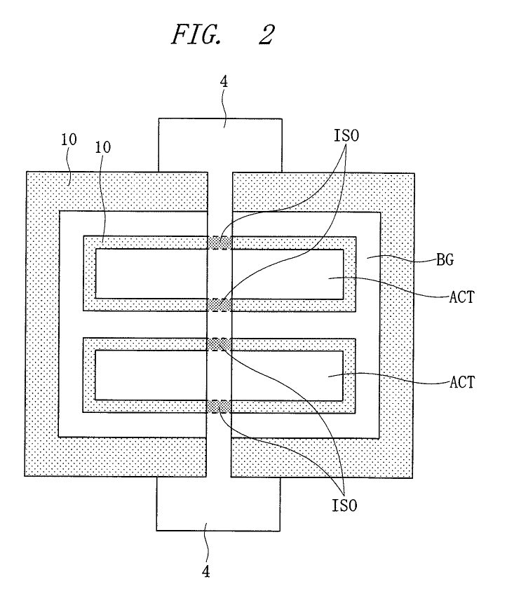

Next, the structure of the nMIS 1n and the pMIS 1p of the semiconductor device according to the first embodiment will be described in detail with reference to FIG. 1 and FIG. 2. FIG. 2 shows a plan view of the principal part of the semiconductor device according to the first embodiment. The nMIS 1n and the pMIS 1p of the first embodiment have the structure described below.

As shown in FIG. 1, the nMIS 1n is disposed in the p well pw which is the p-type semiconductor region formed on the main surface of the SOI substrate with a thin BOX layer 1. The pMIS 1p is disposed in the n well nw which is the n-type semiconductor region formed on the main surface of the SOI substrate with a thin BOX layer 1.

The nMIS 1n has a pair of n-type source/drain regions 2n made of an n-type semiconductor layer and formed so as to be stacked on the main surface of the SOI layer 1i (p well pw). The pair of n-type source/drain regions 2n is disposed at a predetermined interval on the main surface of the SOI layer 1i.

Also, the nMIS 1n has a gate electrode 4 disposed on the main surface of the SOI layer 1i with interposing a gate insulating film 3 therebetween. Sidewalls 5 are provided on both side walls of the gate electrode 4. Therefore, the gate electrode 4 is located at a position on the main surface of the SOI layer 1i between the pair of n-type source/drain regions 2n so as to be planarly sandwiched by the sidewalls 5.

Also, the nMIS 1n has n-type extension regions 6n, which are n-type semiconductor regions formed on the main surface of the SOI layer 1i. The n-type extension regions 6n and the n-type source/drain regions 2n have the same n-type conductivity, and are electrically connected at positions planarly overlapped with each other. The n-type extension regions 6n like these are formed so that carriers can be smoothly transferred between the channel region in the SOI layer 11 below the gate electrode 4 and the n-type source/drain regions 2n.

The nMIS 1n having the above-described structure is covered with an interlayer insulating film 7 on the SOI substrate with a thin BOX layer 1, and is electrically connected to a wiring layer 9 formed on the interlayer insulating film 7 via contact plugs 8 formed in the interlayer insulating film 7. More concretely, the conductive contact plugs 8 are electrically connected to the n-type source/drain regions 2n and the gate electrode 4 of the nMIS 1n, and electrical continuity is provided from outside through the wiring layer 9. The wiring structure made up of the interlayer insulating film 7, the contact plugs 8 and the wiring layer 9 may be similarly formed in the upper layers to form a multilayer wiring structure. The above is the basic structure of the nMIS 1n and the wiring structure of the semiconductor device according to the first embodiment.

The pMIS 1p has a reverse polarity in the semiconductor layer (or semiconductor region) for forming the nMIS 1n, and other than that, it has a similar structure. More concretely, the p-type MIS 1p has the gate insulating film 3, the gate electrode 4 and the sidewalls 5 similar to those of the nMIS 1n. Also, the pMIS 1p has p-type source/drain regions 2p and p-type extension regions 6p having the reverse polarity and similar shape to the n-type source/drain regions 2n and the n-type extension regions 6n of the nMIS 1n. Further, the pMIS 1p can be electrically conducted to the outside through the wiring structure (interlayer insulating film 7, contact plugs 8 and wiring layer 9) similar to that of the nMIS 1n.

The nMIS 1n and the pMIS 1p are disposed in active regions defined by device isolations 10 formed in the main surface of the SOI substrate with a thin BOX layer 1 and are electrically isolated from each other by the device isolations 10.

Here, the device isolation 10 has the so-called STI (Shallow Trench Isolation) structure in which a low-k insulating film having a relative permittivity lower than that of silicon oxide is buried in shallow trenches. Although FIG. 1 shows the case where the nMIS 1n and the pMIS 1p are formed in the p well pw and the n well nw adjacently disposed with interposing the device isolation 10 therebetween, this is not meant to be restrictive.

Next, the structure of the device isolation 10 for insulating the nMIS 1n and the pMIS 1p from each other in the semiconductor device according to the first embodiment will be described in detail with reference to FIG. 1.

At portions where side edge portions of the source/drain regions 2n of the nMIS 1n and the source/drain regions 2p of the pMIS 1p are in contact with the device isolations 10, oxide film sidewalls 11 are provided. Also, in the silicon substrate is below the BOX layer 1b seen from above, the side edge portions of the device isolations 10 extend toward the gate electrode 4 side more than the side edge portions of the n-type source/drain regions 2n of the nMIS in or the side edge portions of the p-type source/drain regions 2p of the pMIS 1p. The side edge portions of the device isolations 10 extended toward the gate electrode 4 can be extended up to near the position just below the sidewalls 5. In FIG. 1, the side edge portion of the device isolation 10 has an elliptical shape, but it may have a square shape. Also, the device isolation 10 below the BOX layer 1b does not have to be formed of a low-k insulating film, and it may be a void. The above is the basic structure of the nMIS 1n, the pMIS 1p, the device isolation 10 and the wiring structure of the semiconductor device according to the first embodiment.

Meanwhile, in the layout when a back gate bias region BG for controlling device characteristics is provided by applying bias voltage from the silicon substrate is side via the BOX layer 1b as shown in FIG. 2, the gate electrode 4 passes across the source/drain regions ACT, the device isolations 10 and the back gate bias regions BG in some cases. In this case, if the device isolation 10 is formed after processing the gate electrode 4, the SOI layer 1i just below the gate electrode 4 and the back gate bias region BG are in contact with each other, and the leakage current flows between the back gate bias region BG and the source/drain region ACT. Alternatively, when the bias voltage is applied to the back gate bias region BG, the bias voltage is directly applied via the SOI layer 1i just below the gate electrode 4 instead of from the silicon substrate is side below the BOX layer 1b. In such a state, the proper ON/OFF characteristics cannot be obtained due to the above-described leakage current, and the control of the device characteristics by the back gate bias voltage cannot be performed.

Therefore, in the first embodiment, only for a portion where the gate electrode 4 passes across the device isolation 10, an isolation portion ISO is formed by using the conventional photolithography method and dry etching method before forming the well. Since the insulating material which forms the isolation portion ISO needs to have a resistance to thermal process, a silicon oxide film is used. Note that a low-k insulating film having a relative permittivity lower than that of silicon oxide may be used for the insulating material which forms the isolation portion ISO. Even when the low-k insulating film is used, it does not affect the circuit operation because it is not just below the source/drain regions ACT and it is a minute region.

Next, the effect achieved when the nMIS 1n and the pMIS 1p according to the first embodiment have the above-described structures will be descried in detail. Note that the effect obtained by the characteristics in process of the nMIS 1n and the pMIS 1p according to the first embodiment will be described later in detail together with the description of the manufacturing method.

In the nMIS 1n and the pMIS 1p of the semiconductor device according to the first embodiment, the following effect can be obtained by the application of the above-described isolation structure. That is, since side edge portions of the device isolations 10 formed in the silicon substrate is are extended to the gate electrode 4 side and the insulating film which makes up the device isolation 10 is made of a low-k insulating film having a relative permittivity lower than that of silicon oxide, the parasitic capacitance generated between the n-type source/drain regions 2n of the nMIS 1n and the p well pw and the parasitic capacitance generated between the p-type source/drain regions 2p of the pMIS 1p and the n well nw can be reduced.

Incidentally, the circuit operation speed of a CMIS device made up of the nMIS 1n and the pMIS 1p is expressed by tpd=RC. Here, tpd is called a circuit delay time and shows the time required for one cycle operation of an inverter, and it is a product of the resistance R and the capacitance C of a transistor. More specifically, a circuit operates faster as the resistance R and the capacitance C become lower. Therefore, in the first embodiment, the parasitic capacitance is reduced by adopting the above-described shape of the device isolation 10 for the isolation structure, so that the performance of the semiconductor device having the nMIS 1n and the pMIS 1p fabricated on the SOI substrate with a thin BOX layer 1 can be improved.

It is more preferable that the nMIS 1n and the pMIS 1p in the semiconductor device according to the first embodiment have the following structure in addition to the above-described basic structure.

The insulating material which forms the gate insulating film 3 can be an insulating film mainly made of silicon oxide, but more preferably a so-called high-k insulating film having a relative permittivity higher than that of silicon oxide. As the gate insulating film 3 having a relative permittivity higher than that of silicon oxide, for example, an insulating film mainly made of silicon oxynitride (SiOₓN_{y}), silicon nitride (SiₓN_{y}), tantalum oxide (Ta₂O₅), titanium oxide (TiO₂), aluminum oxide (Al₂O₃), hafnium oxide (HfO₂) or hafnium silicon oxynitride (HfSiON) can be exemplified. By forming the gate insulating film 3 from a high-k insulating film like this, the equivalent oxide thickness (EOT) can be reduced. In other words, compared with the case where a silicon oxide film is used, the equivalent field effect can be obtained even when the physical thickness of the gate insulating film 3 is increased. By this means, the leakage current can be reduced in the nMIS 1n and the pMIS 1p according to the first embodiment having the above-described effect. As a result, the reliability of the semiconductor device having the nMIS 1n and the pMIS 1p can be further improved.

Also, the conductive material which forms the gate electrode 4 can be a conductive film mainly made of polycrystalline silicon containing an impurity, but more preferably it is a so-called metal gate electrode material using a conductive film mainly made of titanium nitride (TiN), molybdenum nitride (MoN), hafnium silicide (HfSi) or others. This is because, when the metal gate electrode material like this is used to form the gate electrode 4, the gate electrode 4 which is less likely to be depleted can be obtained compared with the case where only a polycrystalline silicon film is used. By this means, the driving current can be improved in the nMIS 1n and the pMIS 1p according to the first embodiment having the above-described effect. As a result, the performance of the semiconductor device having the nMIS 1n and the pMIS 1p can be improved.

Furthermore, the n-type source/drain regions 2n and the p-type source/drain regions 2p can be a semiconductor layer mainly made of silicon, but more preferably the n-type source/drain regions 2n are a semiconductor layer mainly made of mixed crystal of silicon and germanium (Ge) and the p-type source/drain regions 2p are a semiconductor layer mainly made of mixed crystal of silicon and carbon (C). This is because, when the n-type source/drain regions 2n formed by newly stacking on the silicon substrate is are made of the mixed crystal of silicon and germanium and the p-type source/drain regions 2p are made of the mixed crystal of silicon and carbon, the effect of improving the mobility in the channel (carrier mobility in the channel region) made of single crystal silicon can be obtained. By this means, the driving current can be further improved in the nMIS 1n and the pMIS 1p according to the first embodiment having the above-described effect. As a result, the performance of the semiconductor device having the nMIS 1n and the pMIS 1p can be improved.

Also, the n-type source/drain regions 2n and the p-type source/drain regions 2p can be only a semiconductor layer made of silicon or the mixed crystal of silicon and germanium or a semiconductor layer made of the mixed crystal of silicon and carbon as described above, but more preferably a part or whole of the front surface is formed of a metal silicide layer sc. This is because, when the metal silicide layer sc having a resistance value lower than that of a semiconductor layer is provided on the respective front surfaces of the n-type source/drain regions 2n and the p-type source/drain regions 2p, the ohmic connection with the contact plug 8 can be realized. By this means, the driving current can be further improved in the nMIS 1n and the pMIS 1p according to the first embodiment having the above-described effect. As a result, the performance of the semiconductor device having the nMIS 1n and the pMIS 1p can be further improved.

Here, in the case of the structure in which each part of the n-type source/drain regions 2n and p-type source/drain regions 2p is formed of the metal silicide layer sc, the region other than the metal silicide layer sc is the semiconductor layer in the n-type source/drain regions 2n and the p-type source/drain regions 2p. As the metal silicide layer sc, for example, cobalt silicide (CoSi₂) nickel silicide (NiSi), platinum silicide (PtSi), tungsten silicide (WSi₂), molybdenum silicide (MoSi₂) or others can be exemplified. Note that FIG. 1 shows the case where each part of the n-type source/drain regions 2n and p-type source/drain regions 2p and a part of the gate electrode 4 are formed of the metal silicide layer sc. The above is the more preferable structure of the nMIS 1n and the pMIS 1p in the semiconductor device according to the first embodiment.

Next, the manufacturing method of the semiconductor device according to the first embodiment will be described in detail with reference to FIG. 3 to FIG. 15. Note that, in the structure formed by the process described below, the structure similar to that described above is assumed to have the similar effect, and the redundant description is omitted here.

First, as shown in FIG. 3, the buried BOX layer 1b is formed on the main surface of the silicon substrate is, and the SOI layer 1i is further formed on the BOX layer 1b.

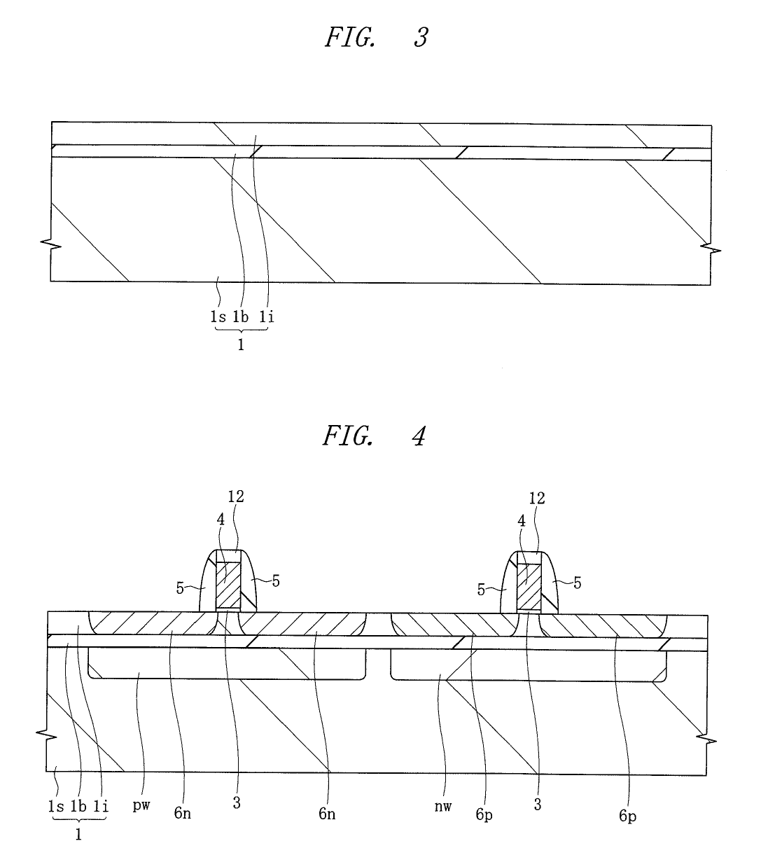

Next, as shown in FIG. 4, the p well pw and the n well nw are formed on the main surface of the silicon substrate 1s and the main surface of the SOI layer 1i. Further, the n-type extension regions 6n and the p-type extension regions 6p are formed on the main surface of the SOI layer 1i, and the gate insulating films 3 and the gate electrodes 4 are formed on the main surface of the SOI layer 1i.

The p well pw and the n well nw are formed by implanting impurities into different regions by the ion implantation method and activating and diffusing the impurities by the heat treatment. When impurities for different conductivity types are implanted into different regions, photoresist films (not shown) patterned by the photolithography method and others are formed, and the impurities are separately implanted with using these patterned films as the masks for the ion implantation. Also, as the heat treatment for the activation and diffusion of the impurities, the heat treatment required in other processes may be utilized in common. By this means, the number of processes can be reduced. Hereinafter, the method of forming other semiconductor regions of respective conductivity types is the same as that described above.

Next, the gate electrodes 4 are formed on the main surfaces of both the regions of the p well pw and the n well nw via the gate insulating films 3 on the main surface of the SOI layer 1i. These are formed by the method described below.

First, the main surface of the SOI layer 1i is oxidized by the thermal oxidation method to form a silicon oxide film to be the gate insulating films 3. Then, a polycrystalline silicon film (may be a silicon germanium film, a metal silicide film, a metal film or others) to be the gate electrodes 4 is formed by the chemical vapor deposition (CVD) method so as to cover the silicon oxide film. Thereafter, the cap insulating film 12 formed of an insulating film mainly made of silicon oxide is formed by the CVD method so as to cover the polycrystalline silicon film.

Subsequently, the cap insulating film 12 is processed by the photolithography method and the dry etching method. Then, the underlying polycrystalline silicon film and silicon oxide film are sequentially processed by the anisotropic etching using the cap insulating film 12 as an etching mask, thereby forming the gate electrodes 4 and the gate insulating films 3, respectively.

As the gate insulating film 3, an insulating film mainly made of silicon oxynitride, silicon nitride, tantalum oxide, titanium oxide, aluminum oxide, hafnium oxide or hafnium silicon oxynitride may be used. It is more preferable to use a low-k insulating film having a relative permittivity lower than that of silicon oxide as the gate insulating film 3 than to use an insulating film mainly made of silicon oxide. The reason and effect thereof are the same as those described above with reference to FIG. 1.

It is more preferable to use a so-called metal gate electrode material using a conductive film mainly made of titanium nitride, molybdenum nitride, hafnium silicide or others as the gate electrode 4. The reason and effect thereof are the same as those described above with reference to FIG. 1.

Subsequently, the sidewalls 5 are formed so as to cover the side walls of the gate electrodes 4. The sidewalls 5 are formed in the following manner. That is, an insulating film mainly made of silicon nitride with a thickness of about 20 to 40 nm is formed on the main surface of the SOI layer 1i by the CVD method or others. Then, dry etching such as the reactive ion etching (RIE) is carried out to the silicon nitride film. In this case, the anisotropic etching is performed to the whole surface of the silicon nitride film without forming the etching mask and the like.

Here, at the step portion of the gate electrode 4, the silicon nitride film is formed to be thicker than that of the flat portion. Therefore, when the anisotropic etching is performed to the whole surface, even if the silicon nitride film of the flat portion is removed, the silicon nitride film can be left so as to cover the side walls of the gate electrode 4. In this manner, the sidewalls 5 made of a silicon nitride film covering the side walls of the gate electrode 4 are formed. The method in which the anisotropic etching is performed to the whole surface of the film so as to leave the desired film in a shape of sidewall on the side wall of the step portion as described above is referred to as etch back.

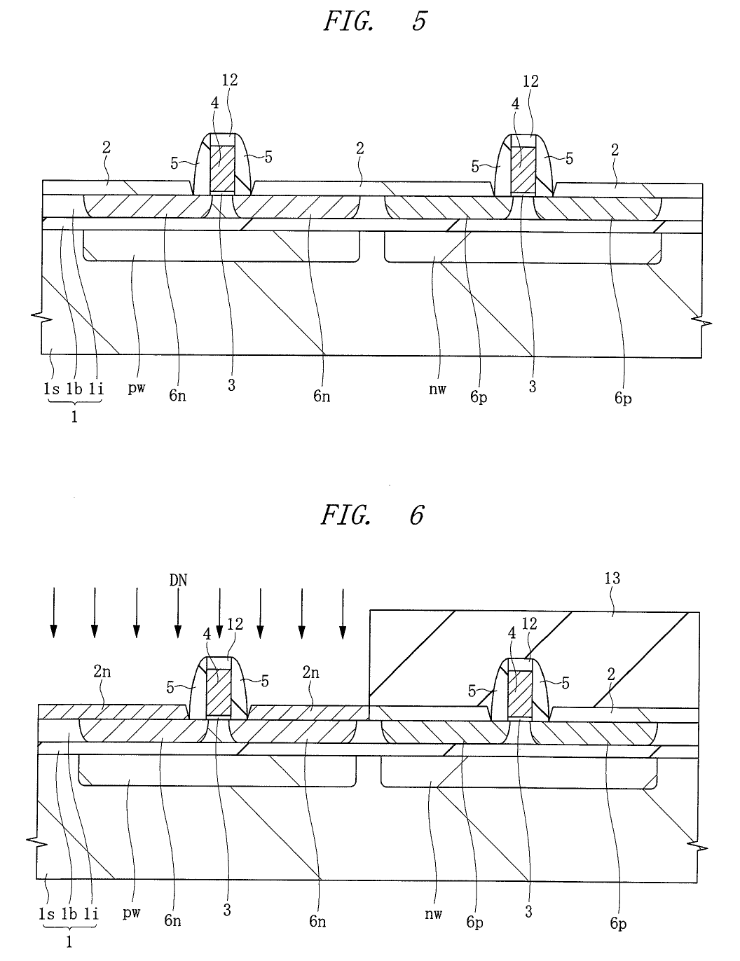

Next, as shown in FIG. 5, the source/drain regions 2 made of a semiconductor layer with a thickness of about 20 to 30 nm are formed on the exposed main surface of the SOI layer 1i. More specifically, in this process, a semiconductor layer is stacked on the regions of the main surface of the SOI layer 1i not covered with the gate electrodes 4 and the sidewalls 5, thereby forming the source/drain regions 2.

For the formation of the source/drain regions 2, a silicon layer is deposited by the low pressure CVD method using, for example, dichlorosilane (SiH₂Cl₂) and hydrogen chloride (HCl) gas. In this method, the silicon layer deposited on the exposed SOI layer 1i is epitaxially grown on the single crystal silicon of the SOI layer 1i. By the selective epitaxial growth as described above, a pair of source/drain regions 2 made of a silicon layer and disposed at a predetermined distance is formed on the main surface of the SOI layer 1i. Note that the silicon layer that is epitaxially grown as the source/drain regions 2 in this process does not contain a predetermined impurity.

Further, in the process described above, the method of forming the source/drain regions 2 by stacking a silicon layer by the selective epitaxial growth has been described. However, in the manufacturing method according to the first embodiment, it is more preferable that the source/drain regions 2 are formed by stacking a semiconductor layer mainly made of mixed crystal of silicon and germanium or mixed crystal of silicon and carbon. The reason therefor is that the effect described with reference to FIG. 1 can be achieved when the mixed crystal of silicon and germanium or the mixed crystal of silicon and carbon is used as the source/drain regions 2.

The semiconductor layer made of the mixed crystal of silicon and germanium (hereinafter, referred to as silicon-germanium mixed crystal layer) is formed by using the selective epitaxial growth method. More concretely, the silicon-germanium mixed crystal layer can be epitaxially grown by the low-pressure CVD method using, for example, dichlorosilane, germanium tetrahydride (GeH₄) and hydrogen chloride gas.

The semiconductor layer made of the mixed crystal of silicon and carbon (hereinafter, referred to as silicon-carbon mixed crystal layer) is formed by using the selective epitaxial growth method. More concretely, the silicon-carbon mixed crystal layer can be epitaxially grown by the vapor phase epitaxial growth method using, for example, dichlorosilane, acetylene (C₃H₈) and hydrogen gas.

The source/drain regions 2 grown here are semiconductor layers obtained by the crystal growth of silicon, and are similarly made to have the n-type conductivity or the p-type conductivity by the ion implantation and the subsequent heat treatment. Hereinafter, the source/drain regions 2 made to have the n-type conductivity by the ion implantation are referred to as the n-type source/drain regions 2n. Also, the source/drain regions 2 made to have the p-type conductivity by the ion implantation are referred to as the p-type source/drain regions 2p. As described above, the n-type source/drain regions 2n and the n-type extension regions 6n are planarly overlapped at their edge portions and are electrically connected to each other. Similarly, the p-type source/drain regions 2p and the p-type extension regions 6p are planarly overlapped at their edge portions and are electrically connected to each other.

Next, as shown in FIG. 6, on the main surface of the SOI layer 1i, a photoresist film 13 is formed by the photolithography method and others so as to cover the region of the n well nw where the pMIS 1p (see FIG. 1) is to be formed later. Thereafter, on the main surface of the SOI layer 1i, the ion implantation DN is carried out to the region of the p well pw where the nMIS 1n (see FIG. 1) is to be formed later with using the photoresist film 13 as an ion implantation mask. In the ion implantation DN, arsenic (As) or phosphorus (P) is implanted as an n-type impurity with the acceleration voltage of 5 keV and the dose amount of 1×10¹⁵ cm⁻². After the ion implantation DN, the photoresist film 13 is removed.

Next, as shown in FIG. 7, on the main surface of the SOI layer a photoresist film 14 is formed by the photolithography method and others so as to cover the region of the p well pw where the nMIS in (see FIG. 1) is to be formed later. Thereafter, on the main surface of the SOI layer 11, the ion implantation DP is carried out to the region of the n well nw where the pMIS 1p (see FIG. 1) is to be formed later with using the photoresist film 14 as an ion implantation mask. In the ion implantation DP, boron (B) or others is implanted as a p-type impurity with the same acceleration voltage and dose amount as those of the ion implantation DN of FIG. 6 above. Then, the photoresist film 14 is removed.

Thereafter, the heat treatment at 1000° C. for 1 second is carried out by, for example, the rapid thermal annealing (RTA) method or the like. By this heat treatment, the implanted impurities are activated and diffused. Through the process above, the n-type source/drain regions 2n and the p-type source/drain regions 2p are formed in the regions in which the impurities are implanted by the ion implantations DN and DP, respectively.

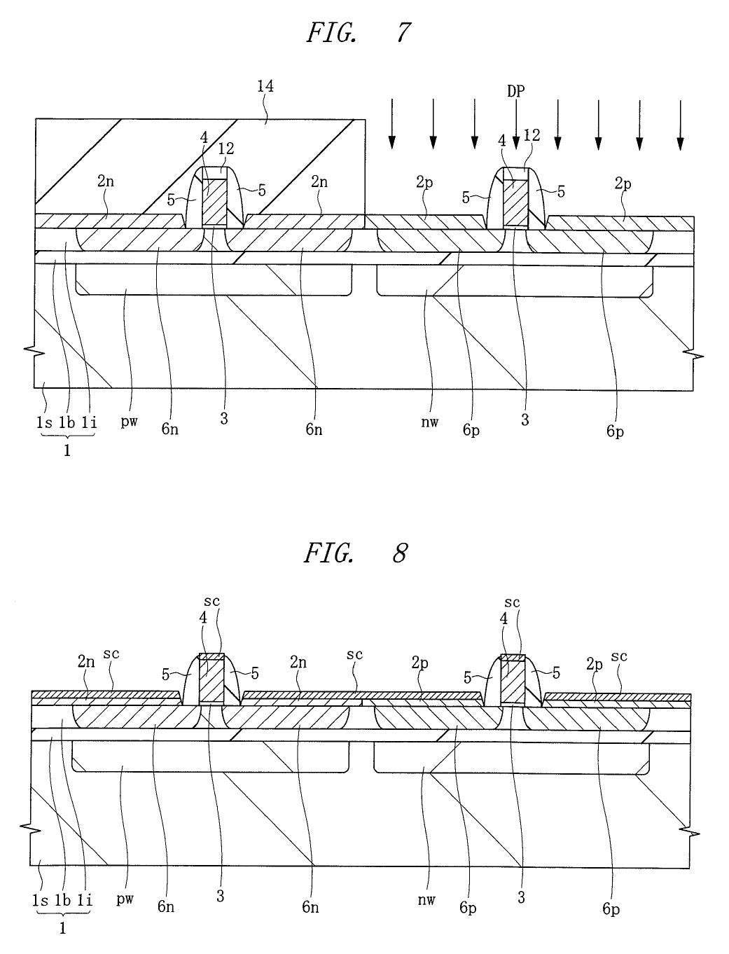

Next, as shown in FIG. 8, the metal silicide layer sc is formed by the so-called salicide technique on the main surface of the SOI layer 1i, that is, on the surfaces of the n-type source/drain regions 2n and p-type source/drain regions 2p made of a semiconductor layer and the surfaces of the gate electrodes 4. First, after removing the cap insulating film 12 on the gate electrode 4, a metal material such as cobalt (Co), nickel (Ni), platinum (Pt), tungsten (W) or molybdenum (Mo) is deposited on the main surface of the SOI layer 1i. Subsequently, by performing the heat treatment, the metal material described above and the portions of silicon exposed on the main surface of the SOI layer 1i (in the first embodiment, the n-type source/drain regions 2n, the p-type source/drain regions 2p and the gate electrodes 4) are chemically reacted (metal silicidation) to form the metal silicide (cobalt silicide, nickel silicide, platinum silicide, tungsten silicide or molybdenum silicide). Thereafter, the portions of the residual metal film not reacted with silicon are removed by the etching, thereby forming the metal silicide layers sc.

Further, in the process of forming the metal silicide layer sc as described above, the impurity implanted into the n-type source/drain regions 2n or the p-type source/drain regions 2p is segregated to the interface of the silicon layer/metal silicide layer sc of the lower end due to the invasion of the metal silicide from the surface (snowplow effect). Therefore, the impurity concentration at the interface of silicon layer/metal silicide layer sc is increased (for example, 1×10²⁰ cm⁻³ or higher). Accordingly, the contact resistance between the silicon layer and the metal silicide layer sc in each of the n-type source/drain regions 2n and the p-type source/drain regions 2p can be sufficiently lowered to an extent not effecting the high-speed operation of the nMIS 1n and the pMIS 1p. The same is true of the case where the n-type source/drain regions 2n are formed by stacking the silicon-germanium mixed crystal layer and the case where the p-type source/drain regions 2p are formed by stacking the silicon-carbon mixed crystal layer.

Note that, by the snowplow effect described above, the impurity concentration of the n-type extension regions 6n becomes lower than the impurity concentration of the n-type source/drain regions 2n, and similarly, the impurity concentration of the p-type extension regions 6p becomes lower than the impurity concentration of the p-type source/drain regions 2p.

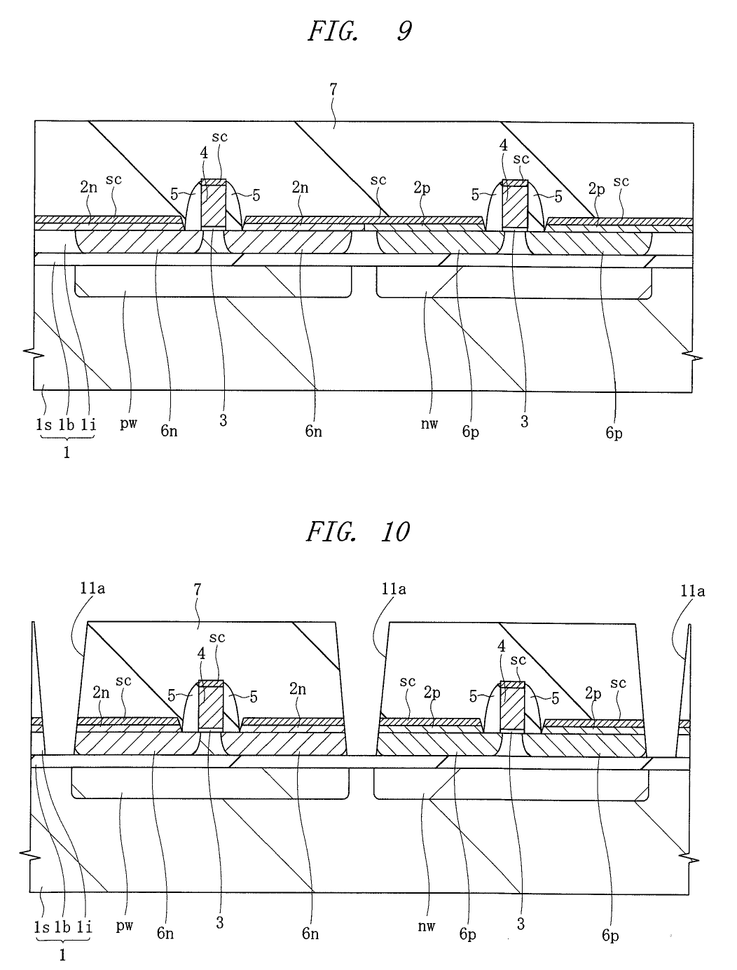

Next, as shown in FIG. 9, the interlayer insulating film 7 is deposited on the main surface of the SOI layer 1i. The interlayer insulating film 7 deposited at this time is formed of a low-k insulating film having the relative permittivity lower than that of silicon oxide (4.2 to 4.0). For example, SiOC (2.8 to 2.5) obtained by adding carbon (C) to SiO₂, SiOF (3.7 to 3.5), SiOB (3.5) and an organic polymer material (2.5 to 2.0) can be exemplified.

Next, as shown in FIG. 10, the device isolations 10 for electrically isolating the nMIS 1n and the pMIS 1p are formed by the photolithography method and the dry etching method. In this process, first isolation trenches 11a are formed by anisotropically etching the interlayer insulating film 7, the metal silicide layer sc, the silicon layer in which the n-type source/drain regions 2n or the p-type source/drain regions 2p are formed and the SOI layer 1i. At this time, the etching gas mixture ratio is adjusted so that the BOX layer 1b is not removed and the anisotropic etching stops on the BOX layer 1b, thereby forming the first isolation trenches 11a.

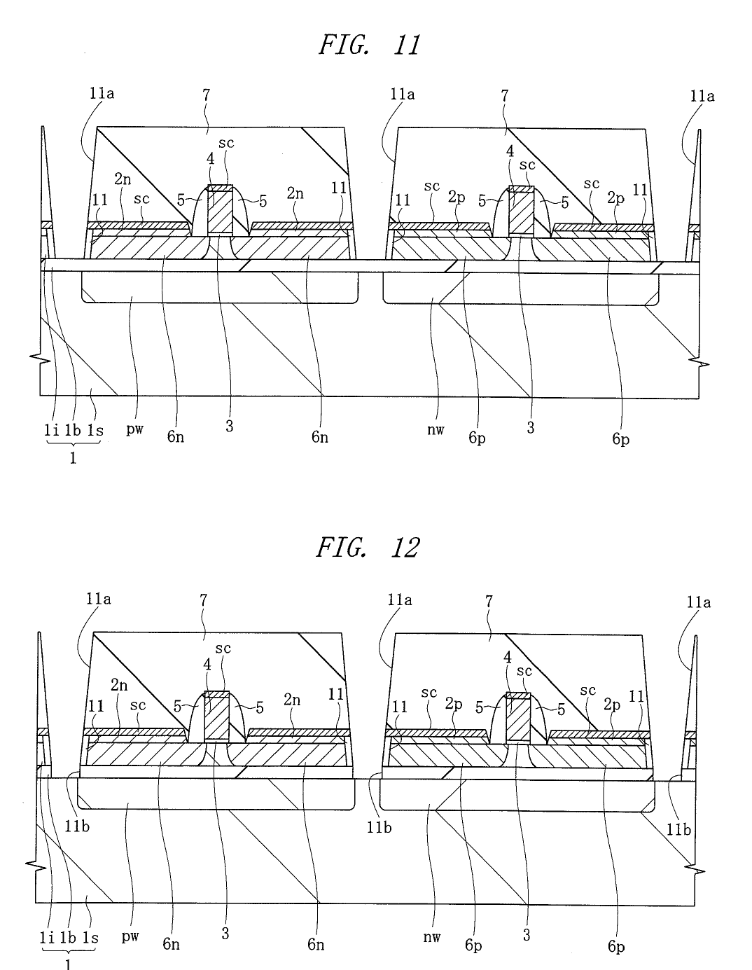

Next, as shown in FIG. 11, the SOI layer 1i and the silicon layer (n-type source drain regions 2 and p-type source/drain regions 2p) exposed on the side walls of the first isolation trenches 11a by the above-described process are oxidized to about 3 nm by the low-temperature plasma oxidation method, thereby forming the oxide film sidewalls 11.

Next, as shown in FIG. 12, the BOX layer 1b, not removed and left at the time when the first isolation trenches 11a are formed, is removed by the anisotropic etching to expose the silicon substrate is, thereby forming second isolation trenches 11b. At this time, the etching gas flow ratio and others are adjusted so that the oxide film sidewalls 11 formed by the above-described low-temperature plasma oxidation method are not removed.

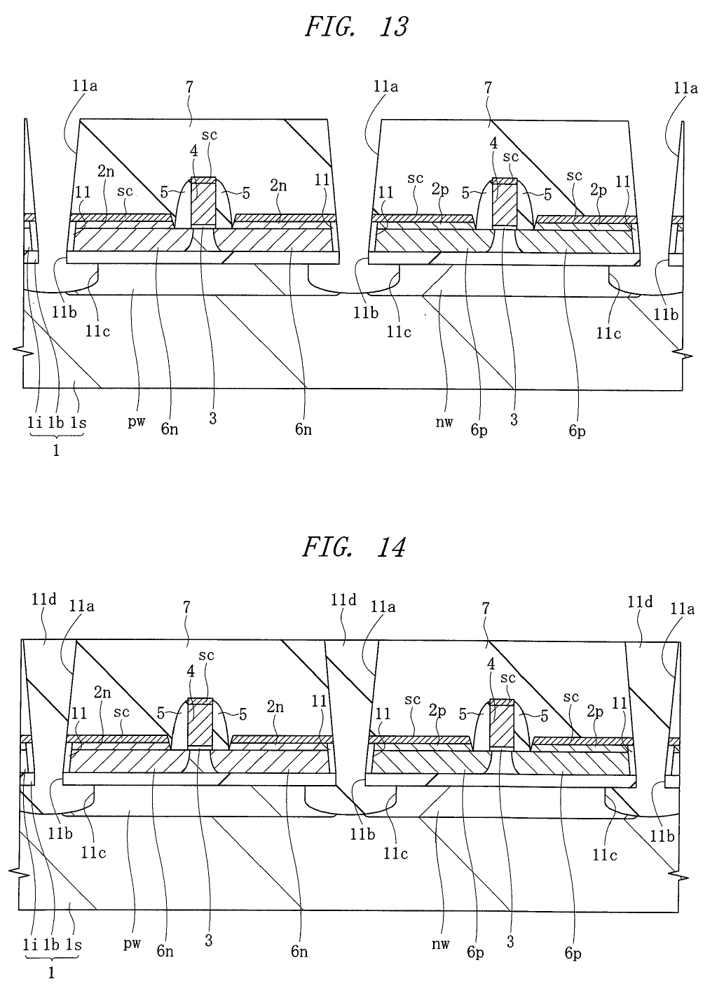

Next, as shown in FIG. 13, the silicon substrate is isotropically etched by using, for example, nitric-hydrofluoric acid from the region where the BOX layer 1b below the second isolation trenches 11b has been removed, thereby forming third isolation trenches 11c. At this time, the concentration is adjusted (for example, HF:HNO₂:CH₃COOH═1:3:8) so that sufficient etching selectivity can be obtained with respect to the interlayer insulating film 7, the metal silicide layer sc, the oxide film sidewalls 11 and the BOX layer 1b which are the exposed regions other than the silicon substrate 1s. At this time, since the etching by nitric-hydrofluoric acid is isotropic etching, the formed third isolation trenches 11c have an elliptical shape. Alternatively, the shape may be a shape other than the elliptical shape, for example, a rectangular shape by using another method. Further, the side edge portions of the third isolation trenches 11c formed at this time extend to the gate electrode 4 side more than the side edge portions of the BOX layer 1b (sidewall portions of the n-type source/drain regions 2n or sidewall portions of the p-type source/drain regions 2p), and also extend to the first isolation trench 11a side or the second isolation trench 11b side more than the side edge portions of the sidewalls 5. More concretely, it is preferable for the high-speed operation of each of the nMIS 1n and the pMIS 1p that the side edge portions of the third isolation trenches 11c are formed between the side edge portions of the sidewalls 5 and the side edge portions of the BOX layer 1b (sidewall portions of the n-type source/drain regions 2n or sidewall portions of the p-type source/drain region 2p) as shown in FIG. 13.

Next, as shown in FIG. 14, an insulating material 11d having the relative permittivity lower than that of silicon oxide is embedded in the first isolation trenches 11a, the second isolation trenches 11b and the third isolation trenches 11c formed by the etching, thereby forming the device isolations 10. The same insulating material as the interlayer insulating film 7 described above may be embedded, and insulating materials other than the interlayer insulating film 7 can be embedded as long as the insulating material has the relative permittivity lower than that of silicon oxide. When the coverage of the insulating material 11d is insufficient, the insulating material 11d is not embedded up to the side edge portions of the third isolation trenches 11c, and voids may be formed inside the third isolation trenches 11c in some cases. However, since the dielectric constant of air is about 1.0, it is preferable for the high-speed operation of the nMIS 1n and the pMIS 1p.

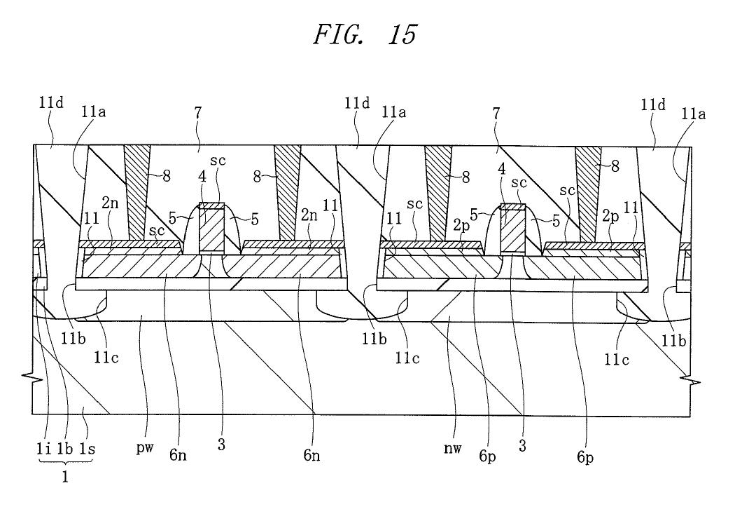

Next, as shown in FIG. 15, the contact plugs 8 are formed in the interlayer insulating film 7 by the photolithography method and the etching method, and the wiring structure made up of the wiring layer 9 described with reference to FIG. 1 is further formed. In the manufacturing method according to the first embodiment, the semiconductor device having the structure shown in FIG. 1 is formed through the process described above. The above is the manufacturing method of the semiconductor device having the nMIS 1n and the pMIS 1p according to the first embodiment.

As described above, in the manufacturing method according to the first embodiment, the device isolations 10 are formed after forming the gate insulating film 3 and the gate electrode 4. More specifically, the gate insulating film 3 and the gate electrode 4 can be formed in the state where there is no difference in height (step) at the interface between the upper surface of the device isolation 10 and the upper surface of the SOI layer 1i. Therefore, the excessive removal of the substrate (the SOI layer 1i on both sides of the gate electrode 4 is hollowed by the excessive etching) or the residue (a material of the gate electrode 4 and a material of the gate insulating film 3 are left at step portions between the upper surface of the device isolation 10 and the upper surface of the SOI layer 1i due to the insufficient etching) at the time when processing the gate insulating film 3 and the gate electrode 4 can be prevented. By this means, the increase in the substrate leakage current due to the excessive removal of the substrate can be prevented, and the degradation in the device characteristics of the nMIS 1n and the pMIS 1p caused by the parasitic capacitance formed by the residue can be prevented.

Further, in the manufacturing method according to the first embodiment, the device isolation 10 is formed after forming the metal silicide layer sc in the process of FIG. 8. More specifically, even when the HF cleaning is performed just before forming the metal silicide layer sc, the insulating material 11d that forms the device isolation 10 is not recessed. Therefore, the electrical contact between the silicon substrate is below the BOX layer 1i and the SOI layer 1i by the diffusion of metal silicide can be prevented. Accordingly, the degradation in device characteristics due to the substrate leakage current flowing from the SOI layer 1i to the silicon substrate is can be prevented.

As described above, since the device isolation 10 is formed after forming the gate electrode 4 and the metal silicide layer sc, the occurrence of the excessive removal of the substrate and the residue at the time of processing the gate electrode 4 can be suppressed, and the electrical contact between the SOI layer 1i and the silicon substrate is at the time of forming the metal silicide layer sc can be prevented. Accordingly, the nMIS 1n and the pMIS 1p can be formed on the main surface of the SOI substrate with a thin BOX layer 1 without degrading transistor characteristics such as ON/OFF characteristics.

### Second Embodiment

A semiconductor device according to the second embodiment will be described while comparing with the above-described semiconductor device according to the first embodiment.

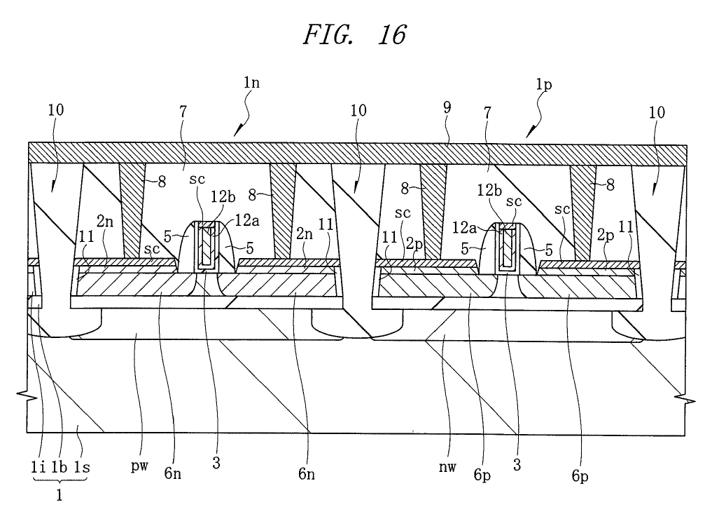

As shown in FIG. 16, the nMIS 1n and the pMIS 1p of the semiconductor device according to the second embodiment have a different structure in the principal part of the gate electrode 4 thereof from the above-described semiconductor device according to the first embodiment (see FIG. 1). Note that the semiconductor device according to the second embodiment has the similar structure to the semiconductor device according to the first embodiment other than the structure described below and also has the same effect, and the redundant description is omitted here.

In the nMIS 1n and the pMIS 1p of the semiconductor device according to the second embodiment, the gate insulating film 3 is formed along the inner side of the sidewalls 5, and a first gate electrode 12a and a second gate electrode 12b are embedded inside the gate insulating film 3. This structure is fabricated by the gate-last process using the Damascene technique as described in the manufacturing method later. By this process, a high-k insulating film having the high relative permittivity can be applied to the gate insulating film 3. Since the relative permittivity is high, the equivalent oxide thickness can be realized with a relatively large thickness in comparison to the silicon oxide film that has been used for the gate insulating film 3. Since the thickness of the gate insulating film 3 can be increased, the gate leakage current flowing from the first and second gate electrodes 12a and 12b to the SOI layer 1i can be suppressed. Further, since the gate length can be shrunk in accordance with the scaling law, the ON current (Ion) is increased. Also, this gate-last process can be used together with the STI-last process as described in the second embodiment. As described above, by applying the second embodiment, the gate leakage current of the nMIS 1n and the pMIS 1p can be suppressed, and the Ion characteristics can be improved. Therefore, the transistor characteristics of the nMIS 1n and the pMIS 1p can be improved by applying the second embodiment.

Next, a manufacturing method of the semiconductor device having the above-described effect will be described. In the second embodiment, the processes not particularly mentioned in the manufacturing method are the same as those of the above-described manufacturing method according to the first embodiment (FIG. 3 to FIG. 15). With respect to the effect having each of the processes of the manufacturing method of the semiconductor device according to the second embodiment, the same effect can be achieved if the process is the same as that of the first embodiment, and the redundant description is omitted here.

First, in the manufacturing method of the semiconductor device according to the second embodiment, as shown in FIG. 2 above, the SOI substrate with a thin BOX layer 1 is prepared.

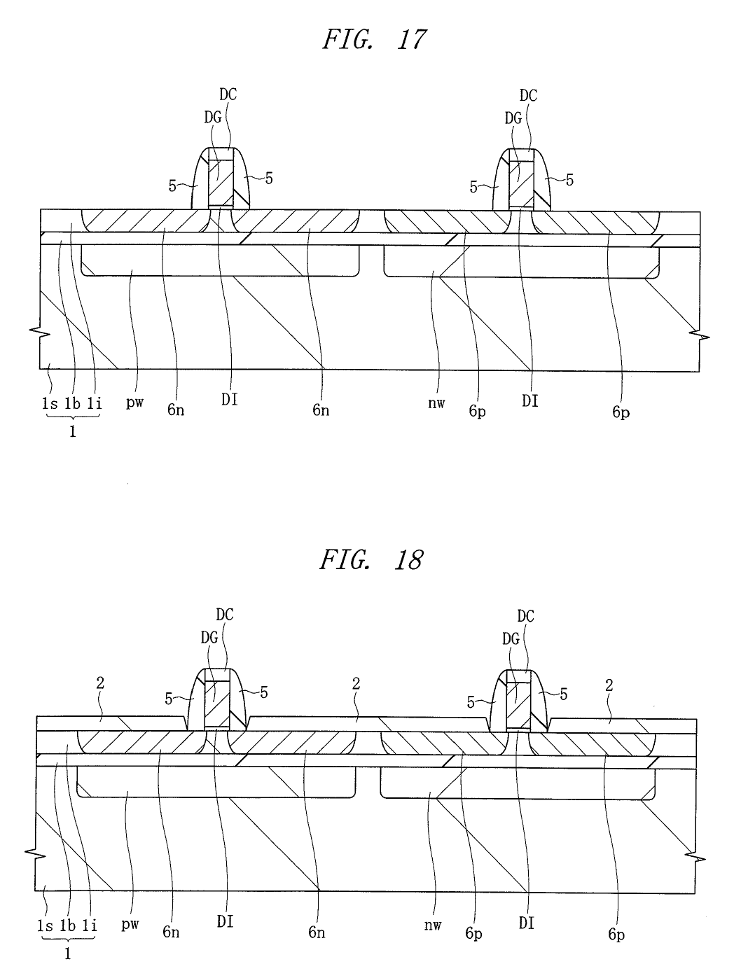

Next, as shown in FIG. 17, the p well pw, the n well nw, dummy gate insulating films DI, dummy gate electrodes DG and dummy gate cap films DC are formed, and further, the n-type extension regions 6n and the p-type extension regions 6p are formed.

On the respective main surfaces of the SOI layers 1i of the p well pw and the n well nw, the dummy gate electrodes DG are formed via the dummy gate insulating films DI. These are formed by the same method as that described in the first embodiment. First, the main surface of the SOI layer 1i is oxidized by the thermal oxidation method or the like, thereby forming a silicon oxide film to be the dummy gate insulating films DI. Then, a polycrystalline silicon film (may be a silicon germanium film, a metal silicide film, a metal film or others) to be the dummy gate electrodes DG is formed by the CVD method or others so as to cover the silicon oxide film. Thereafter, the dummy gate cap film DC formed of an insulating film mainly made of silicon oxide is formed by the CVD method or others so as to cover the polycrystalline silicon film.

Subsequently, the dummy gate cap film DC is processed by the photolithography method and the anisotropic etching method. Then, the underlying polycrystalline silicon film and silicon oxide film are sequentially processed by the anisotropic etching using the dummy gate cap film DC as an etching mask, thereby forming the dummy gate electrodes DG and the dummy gate insulating films DI. Subsequently, the sidewalls 5 are formed so as to cover the side walls of the dummy gate electrodes DG.

Next, as shown in FIG. 18, a semiconductor layer is stacked on the main surface of the SOI layer 1i by the selective epitaxial growth, thereby forming the source/drain regions 2.

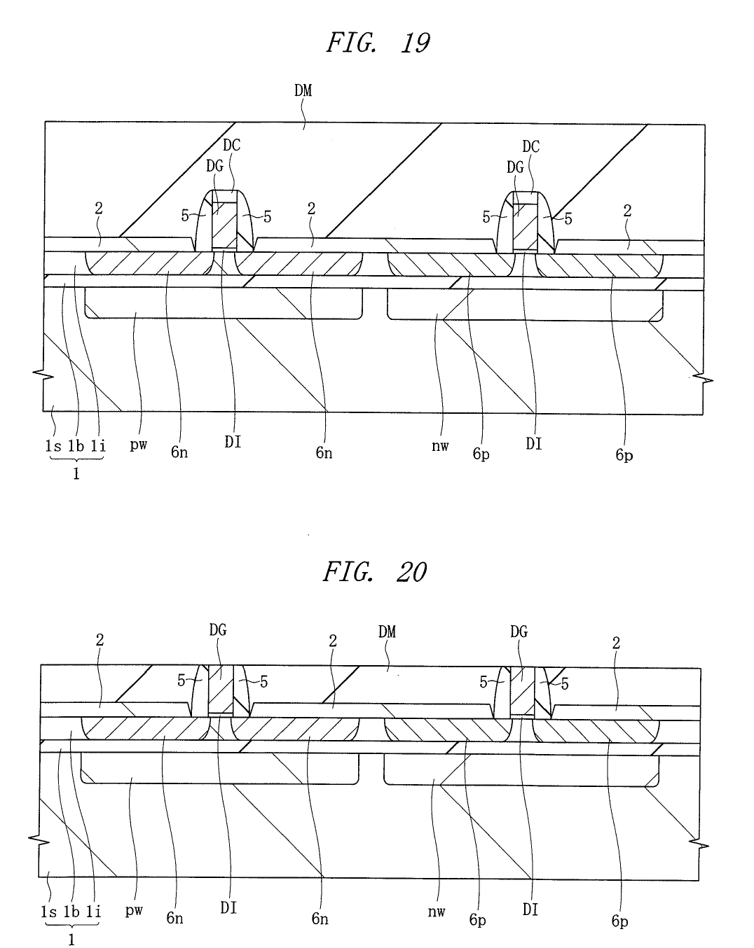

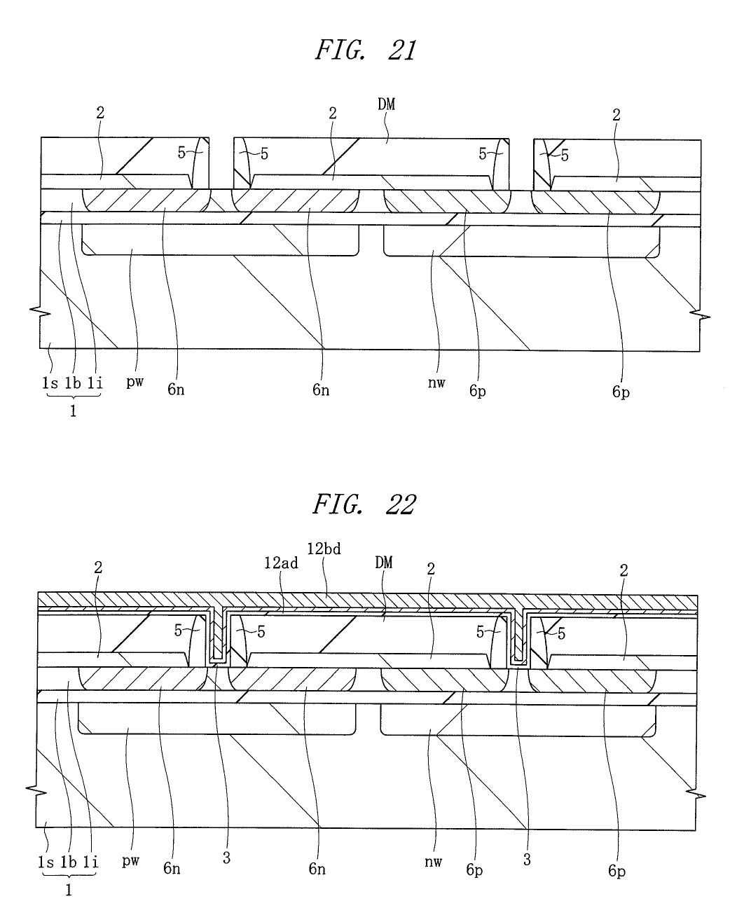

Next, as shown in FIG. 19 to FIG. 21, a dummy film DM is deposited on the main surface of the SOI layer 1i, and then, the dummy film DM and the dummy gate cap film DC are ground by the chemical mechanical polishing (CMP) method until the front surface side of the dummy gate electrodes DG is exposed. Thereafter, the dummy gate electrodes DG and the dummy gate insulating films DI are removed by the wet etching.

Next, as shown in FIG. 22, the gate insulating film 3, a first conductive film 12ad and a second conductive film 12bd are sequentially deposited by the CVD method on the main surface of the SOI layer 1i. It is more preferable that the gate insulating film 3 is the so-called high-k insulating film having the relative permittivity higher than that of silicon oxide. As the high-k insulating film having the relative permittivity higher than that of silicon oxide, for example, an insulating film mainly made of tantalum oxide, titanium oxide, aluminum oxide, hafnium oxide or hafnium silicon oxynitride can be exemplified. Also, it is more preferable that a conductive material that forms the first conducive film 12ad is the so-called metal gate electrode material using a conductive film mainly made of titanium nitride, molybdenum nitride, hafnium silicide or others. Further, it is more preferable that this first conductive film 12ad is a metal material having a work function suitable for the transistor characteristics of the nMIS 1n and the pMIS 1p because it takes a role of adjusting the work function that affects the threshold voltage of the nMIS 1n and the pMIS 1p. In addition, it is more preferable that the second conductive film 12bd is the so-called metal gate electrode material using a conductive film mainly made of a metal material having a low electric resistivity such as aluminum (Al), copper (Cu), tungsten (W), titanium (Ti) or others regardless of the work function adjustment.

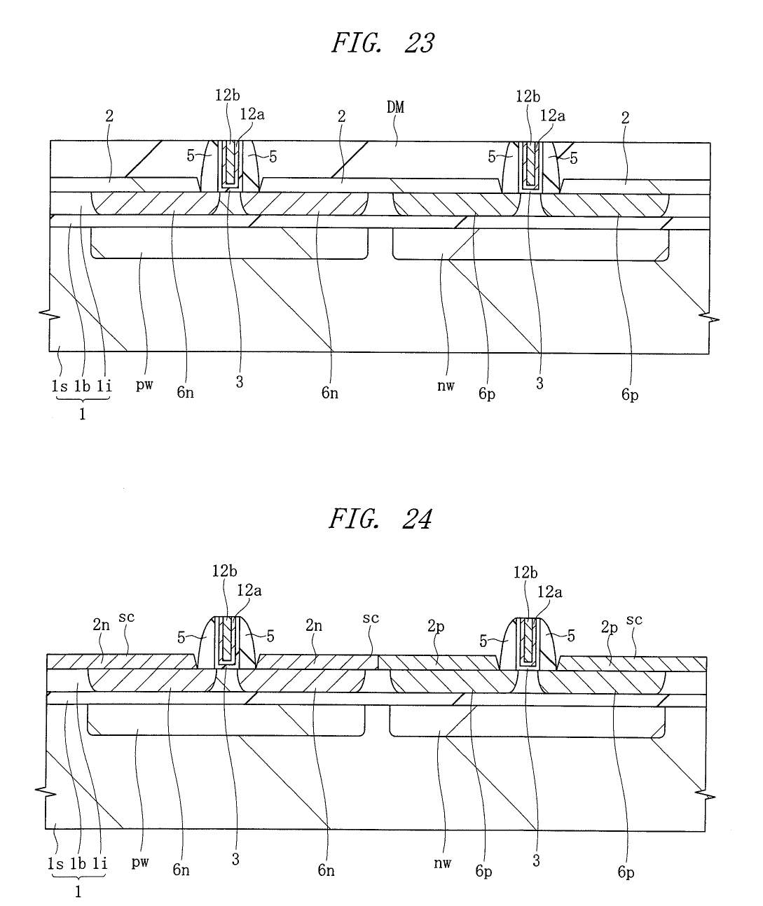

Next, as shown in FIG. 23, the gate insulating film 3, the first conductive film 12ad and the second conductive film 12bd deposited in the above-described process are ground to the height of the dummy film DM by the CMP method, and further, the dummy film DM is removed as shown in FIG. 24. By this means, the first gate electrodes 12a and the second gate electrodes 12b are formed, and the gate electrodes 4 each made up of the first gate electrode 12a and the second gate electrode 12b are formed. Next, after an n-type impurity is ion-implanted into the region of the nMIS 1n and a p-type impurity is ion-implanted into the region of the pMIS 1p, the heat treatment is performed, thereby forming the n-type source/drain regions 2n and the p-type source/drain regions 2p.

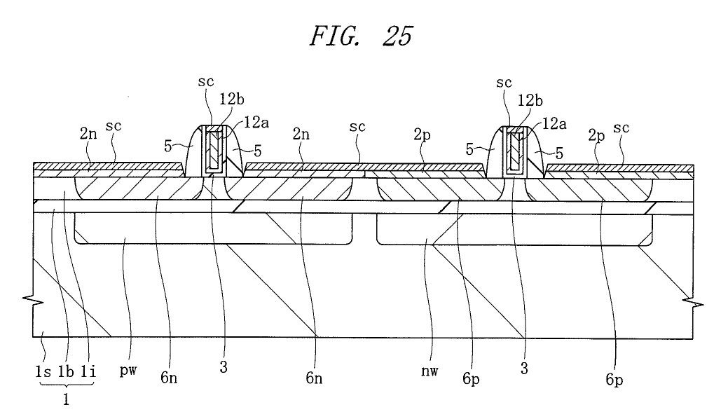

Next, as shown in FIG. 25, the metal silicide layers sc are formed by the same method as that described in the first embodiment. Thereafter, the process for the contact plugs 8 and the wiring layers 9 similar to that described in the first embodiment is performed, so that the semiconductor device having the structure described with reference to FIG. 16 is formed. The above is the manufacturing method of the semiconductor device having the nMIS 1n and the pMIS 1p according to the second embodiment.

Next, the effect achieved by the above-described structure of the manufacturing method of the semiconductor device according to the second embodiment will be described in more detail.

As described above, in the manufacturing method of the semiconductor device according to the second embodiment, when materials for forming the gate insulating film 3, the first gate electrode 12a and the second gate electrode 12b are deposited after removing the dummy gate electrode DG, there is no step portions between the upper surface of the SOI layer 1i and the upper surface of the device isolation 10. Therefore, the embedding properties of the material of the gate edge portions can be improved, and the reduction in width of the effective gate electrode can be suppressed. Since the reduction in width of the effective gate electrode can be suppressed, the nMIS 1n and the pMIS 1p manufactured by applying the manufacturing method of the semiconductor device according to the second embodiment exhibit better Ion properties compared with the nMIS 1n and the pMIS 1p manufactured only by the Damascene gate process without applying the manufacturing method of the semiconductor device according to the first embodiment. As a result, the performance of the semiconductor device can be further improved.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, a halo region may be formed after the process of forming the extension regions (n-type extension regions 6n and p-type extension regions 6p) described in the first and second embodiments (process described with reference to FIG. 3). For its formation, first, an appropriate impurity for the n-type conductivity or the n-type conductivity is obliquely ion-implanted under the conditions of, for example, the acceleration voltage of 5 keV and the dose amount of 1×10¹³ cm⁻². Thereafter, the heat treatment is performed at 1000° C. for about 1 second by the RTA method or the like.

The present invention can be applied to, for example, the semiconductor industry necessary for conducting the information processing in a personal computer, a mobile device and others.

What is claimed is:

1. A semiconductor device comprising:
a first semiconductor region of a first conductivity type and a second semiconductor region of a second conductivity type different from the first conductivity type disposed at a predetermined interval on a main surface of a semiconductor substrate;
a pair of semiconductor layers disposed at a predetermined distance on a main surface of the first semiconductor region;
a pair of source/drain regions of the second conductivity type formed on the pair of semiconductor layers;
a gate electrode sandwiched between the pair of source/drain regions; and
a device isolation formed between the first semiconductor region and the second semiconductor region,
wherein a side edge portion of the device isolation extends toward a gate electrode side more than a side edge portion of the source/drain region.

2. The semiconductor device according to claim 1,
wherein the device isolation is made up of an isolation trench and an insulating material having a relative permittivity lower than that of silicon oxide and embedded in the isolation trench.

3. The semiconductor device according to claim 2,
wherein the insulating material is SiOC, SiOF, SiOB or an organic polymer material.

4. The semiconductor device according to claim 1,
wherein the device isolation is made up of an isolation trench and an insulating material having a relative permittivity lower than that of silicon oxide and embedded in the isolation trench, and a void in which the isolation material is not embedded is formed in a part of the device isolation.

5. The semiconductor device according to claim 1,
wherein the semiconductor layer contains silicon, mixed crystal of silicon and germanium, or mixed crystal of silicon and carbon.

6. The semiconductor device according to claim 1,
wherein a metal silicide layer is formed on a surface of the semiconductor layer.

7. The semiconductor device according to claim 1,
wherein a thickness of the semiconductor layer is 20 to 30 nm.

8. The semiconductor device according to claim 1,
wherein the gate electrode is made up of a first gate electrode and a second gate electrode, and the first gate electrode is formed on side surfaces and a bottom surface of the second gate electrode.

9. The semiconductor device according to claim 1,
wherein the gate insulating film formed between the semiconductor substrate and the gate electrode is an insulating film mainly made of tantalum oxide, titanium oxide, aluminum oxide, hafnium oxide or hafnium silicon oxynitride.

10. The semiconductor device according to claim 1,
wherein the semiconductor substrate is made up of a silicon substrate and an SOI layer formed on a main surface of the silicon substrate via a BOX layer, and the semiconductor layer is formed on a part of a main surface of the SOI layer on which the gate electrode is not formed.

11. The semiconductor device according to claim 10,
wherein a thickness of the SOI layer is 4 nm to 100 nm.

12. The semiconductor device according to claim 10,
wherein a thickness of the BOX layer is 3 nm to 50 nm.

13. A manufacturing method of a semiconductor device comprising:
(a) a step of preparing a substrate having a silicon substrate and an SOI layer formed on a main surface of the silicon substrate via a BOX layer;
(b) a step of forming a first semiconductor region of a first conductivity type and a second semiconductor region of a second conductivity type different from the first conductivity type disposed at a predetermined interval on a main surface of the substrate;
(c) a step of forming a gate insulating film and a gate electrode on a main surface of the SOI layer in the first semiconductor region and forming sidewalls made of an insulating film on side walls of the gate electrode;
(d) a step of forming a semiconductor layer on a part of the main surface of the SOI layer on which the gate electrode and the sidewalls are not formed;
(e) a step of forming a pair of source/drain regions of the second conductivity type on the semiconductor layer;
(f) a step of forming an interlayer insulating film on the main surface of the substrate;
(g) a step of sequentially etching the interlayer insulating film, the semiconductor layer and the SOI layer located on a position between the first semiconductor region and the second semiconductor region, thereby forming a first isolation trench in the interlayer insulating film, the semiconductor layer and the SOI layer;
(h) a step of forming oxide film sidewalls on the semiconductor layer and the SOI layer exposed on side walls of the first isolation trench;
(i) a step of forming a second isolation trench by removing the BOX layer located below the first isolation trench;
(j) a step of etching the silicon substrate from a region from which the BOX layer has been removed, thereby forming a third isolation trench in the silicon substrate; and
(k) a step of embedding an insulating material in the first, second and third trenches,
wherein, in the step (j), a side edge portion of the third isolation trench is formed so as to extend toward a gate electrode side more than a side edge portion of the source/drain region.

14. The manufacturing method of the semiconductor device according to claim 13,
wherein the etching of the silicon substrate in the step (j) is isotropic etching.

15. The manufacturing method of the semiconductor device according to claim 13,
wherein the etching of the interlayer insulating film, the semiconductor layer and the SOI layer in the step (g) is anisotropic etching.

16. The manufacturing method of the semiconductor device according to claim 13, further comprising, between the step (e) and the step (f):
(l) a step of forming a metal silicide layer on a surface of the semiconductor layer.

17. The manufacturing method of the semiconductor device according to claim 13,
wherein the insulating material embedded in the first, second and third isolation trenches is SiOC, SiOF, SiOB or an organic polymer material.

18. The manufacturing method of the semiconductor device according to claim 13,
wherein a thickness of the SOI layer is 4 nm to 100 nm.

19. The manufacturing method of the semiconductor device according to claim 13,
wherein a thickness of the BOX layer is 3 nm to 50 nm.
